(19) United States
(12) Patent Application Publication
(10) Pub. No.: US 2002/0017834 A1
(43) Pub. Date: Feb. 14, 2002

(54) Acoustically actuated mems devices

(76) Inventor: Robert I. MacDonald, Manotick (CA)

Correspondence Address: JDS Uniphase Corporation, Intellectual Property Dept., 570 West Hunt Club Road, Nepean, ON, K2G 5W8, CA

(21) Appl. No.: 09/899,244

(22) Filed: Jul. 6, 2001

Related U.S. Application Data
(60) Provisional application No. 60/216,535, filed on Jul. 6, 2000.

(51) Int. Cl. H01L 41/08

(52) U.S. Cl. 310/328

(57) ABSTRACT

The invention provides a MEMS acoustic actuator having a substrate, an acoustic wave generator for generating an acoustic wave, the acoustic wave generator is disposed on the substrate, and a moveable element for receiving the acoustic wave, said moveable element is operatively connected to the acoustic wave generator such that the acoustic wave generator is capable of exerting sufficient acoustic radiation pressure for moving the moveable clement. The moveable element has a planar surface for receiving and deflecting the acoustic wave.

### FIELD OF THE INVENTION

The present invention relates generally to the field of MEMS devices and more specifically to an acoustically actuated MEMS element.

### BACKGROUND OF THE INVENTION

Micro-electromechancial systems (MEMS) are micro devices or systems that combine electrical, mechanical and optical components and are fabricated using integrated circuit (IC) compatible batch-processing techniques. They range in size from micrometers to millimeters. MEMS provide sensing and actuation in a manner (size, cost & construction) that integrates seamlessly with traditional IC and opto-electronic components.

New applications and uses for micro-electromechancial systems (MEMS) are continuously being developed. Many micro-electromechancial systems typically include one or more micro-actuated devices that are machined into silicon wafers or other substrates in part using many of the batch fabrication techniques developed for fabricating electronic devices. Micro-actuated devices typically include movable members or components that either are driven by an electrical stimulus to perform mechanical tasks or are sensory elements that generate an input to an electronic system in response to a physical stimulus or condition. In addition, by virtue of the commonality of many manufacturing processes, control and other support electronics may also be fabricated onto the same substrates as the micro-actuated devices, thereby providing single chip solutions for many MEMS applications.

Micro-devices based on micron and millimeter scale MEMS technology are widely used in valve-containing micro-fluidic controls systems, micro-sensors, and micro-machines. Currently, MEMS valves are used in automobiles, medical instrumentation, or process control applications, and in conjunction with appropriate sensors can provide accurate determinations of pressure, temperature, acceleration, gas concentration, and many other physical or chemical states. Micro-fluidic controls include micro-valves for handling gases or liquids, flow gauges, and ink jet nozzles, while micro-machines include micro-actuators, movable micro-mirror systems, or tactile moving assemblies. For example, one general application of MEMS is that of fluid delivery or regulation systems, e.g., in biomedical or biological applications, such as portable or implantable drug delivery systems, biochemical analysis applications, such as chip immuno sensors and portable gas chromatographs, air flow control applications such as heating, ventilation and air conditioning systems, robotics applications, such as effectors for micro-fluidic manipulators, food and pharmaceutical applications, such as mass flow controllers, and micro fuel injectors and valving systems, among others. A micro-pump, for example, is a MEMS device suitable for use in the delivery of fluid between two ports. Similarly, a micro-valve is a MEMS device suitable for use in selectively permitting or blocking the passage of a fluid through port.

However, it has been found that many conventional micro-pumps and micro-valves require high drive voltages to attain adequate fluid delivery rates for many applications. For example, micro-pumps and micro-valves have been developed that rely on electrostatic motive forces and require drive voltages of several hundred volts. If used in conjunction with conventional signal control or other processing electronics (whether or not on the same substrate), often a separate power supply or voltage regulator is required to drive such MEMS devices, since most electronic processing devices operate in the range of 1-5 volts. Moreover, in many biomedical or biological applications a serious safety concern is raised with respect to such devices by virtue of the potential for electrical breakdown at high voltages.

It is desirable to actuate MEMS devices without requiring solid mechanical contact, i.e. without physically touching them. Mechanical contact has many disadvantages such as stiction, wear, coupling between orthogonal axes, low speed and imprecision. Unfortunately the simplest method of non-contact MEMS actuation, electrostatic attraction, is unstable. The actuation force increases as the deflection increases, a situation that can lead to runaway actuation and mechanical collapse. The controllable range of motion is significantly less than the capability of the actuator.

Instability arises because the electrostatic actuator is a pulling actuator, strengthening the actuation force as it reduces the range over which it acts. By contrast a pushing actuator would act to increase the actuation distance and therefore exert reduced force actuation increases, in intrinsically stable design. The range of motion is set by the force that the actuator can apply rather than by stability considerations.

Other methods of actuating MEMS devices include thermal actuation as a contacting method and electromagnetic actuation, using, both pushing and pulling forces.

U.S. Pat. No. 5,945,898 to Judy et al., incorporated herein by reference, discloses a magnetic microactuator. However, global actuation by a magnetic field is simple but has many disadvantages. The package contains an electromagnet that dominates the physical volume and the power consumption of the device. The magnetic circuit is a critical part of the package because the field in the region of the mirrors of an optical switch, for example, must be strong, uniform, and correctly oriented to within a few degrees. This requirement necessitates an extra MEMS structure (a nickel pole piece) to redirect the field near the top of the mirror travel. The inductance of the magnetic structure is high and the magnet must be driven very hard to establish the field in the required time (˜5 ms). A concern for a strong and rapidly changing magnetic field within a package that also contains electronics will be electromagnetic induction in the circuits. There is some risk that there may be remnant magnetization that will interfere with switch operation. While remnant magnetization might be accommodated, it will be at the cost of complexity and speed. Finally. The magnetic drive is bulky and heavy and imposes a package height considerably greater than the optical system alone requires.

The design of some optical MEMS devices is sensitive to the range of actuation. For example, in so-called “3-D” MEMS optical switches arrays of micro-mirrors are steered to guide input optical beams to output ports. The maximum tilt of the micro-mirrors sets the minimum length of the optical system. A range of about 5 degrees is typical for electrostatically driven mirrors as a compromise among MEMS fabrication and control issues, the voltage required to drive the mirror and the safe drive range. With such a tilt restriction the optical throw, and hence the switch, may need to be many tens of cm long. Hence, it is desired to employ a non-contact method of MEMS actuation that uses a pushing force rather than a pulling force so as to establish a controllable mirror tilt over a wide angular range.

Like any physical wave, a sound wave exerts radiation pressure. This pressure, while small, can be used to manipulate objects. One example is in micro-gravity materials processing where acoustic radiation pressure is used to localize materials for thermal processing without contamination from the walls of a chamber. MEMS actuation shares some of the properties to micro-gravity manipulation. The elements to be moved are of such low mass that forces other than gravity may dominate, such as friction for example. In this regime acoustic radiation pressure can be effective.

MEMS ultrasound transducers can have more wide-ranging application in optics as they have significant advantages as non-contact mechanical actuators for MEMS-optical devices, offering a variety of advantages over the electrostatic, magnetic and thermal actuators now being developed for these applications. Ultrasound actuation is stable, stiction-free, hysteresis-free, and requires low power. For example, a common application for acoustic actuation is the actuation of planar mirrors for 2-D and 3-D MEMS optical switches by acoustic radiation pressure.

MEMS actuators made as membrane capacitors are very simple. Their yield and reliability are high by comparison with more complex actuator devices.

It is an object of this invention to provide an acoustically actuated MEMS device

It is an further object of the invention to provide a method of making an acoustically actuated MEMS device.

Another object of this invention is to provide low cost actuated MEMS devices requiring low drive voltage.

It is yet a further object of the invention to provide a non-contact method and apparatus of actuating a MEMS device.

### SUMMARY OF THE INVENTION

In accordance with the invention there is provided, a MEMS acoustic actuator comprising a substrate, an acoustic wave generator for generating an acoustic wave, said acoustic wave generator being disposed on the substrate, and a moveable element for receiving the acoustic wave, said moveable element being operatively connected to the acoustic wave generator such that the acoustic wave generator is capable of exerting sufficient acoustic radiation pressure for moving said moveable element.

In accordance with a further embodiment of the invention, the moveable element comprises a planar surface for receiving and deflecting the acoustic wave.

In accordance with an embodiment of the invention, the moveable element is one of a mirror, a waveguide, it diffraction grating, a holographic optical element, a Fresnel lens, and a valve.

In accordance with another aspect of the invention, there is provided, a method of actuating a MEMS device comprising the steps of launching an acoustic wave, and receiving the acoustic wave with a moveable element such that the acoustic wave exerts sufficient radiation pressure for moving said moveable element.

Advantageously, acoustically actuated MEMS devices are stable, stiction-free, hysteresis-free, and require low power. MEMS type acoustic transducers are thinner and lighter since there is no magnet or pole-piece and they more easily allow MEMS mirror chips to be assembled into optical arrays without intervening fiber. A further advantage of acoustic actuation is that there is no magnetic remnant issue. Since acoustic actuation is an non-contacting method using a pushing force rather than a pulling force to actuate the MEMS device, common stiction problems associated with employing pulling forces arc obviated.

BRIEF DESCRIPTION OF THE DRAWINGS

Exemplary embodiments of the invention will now be described in conjunction with the following drawings wherein like numerals represent like elements, and wherein:

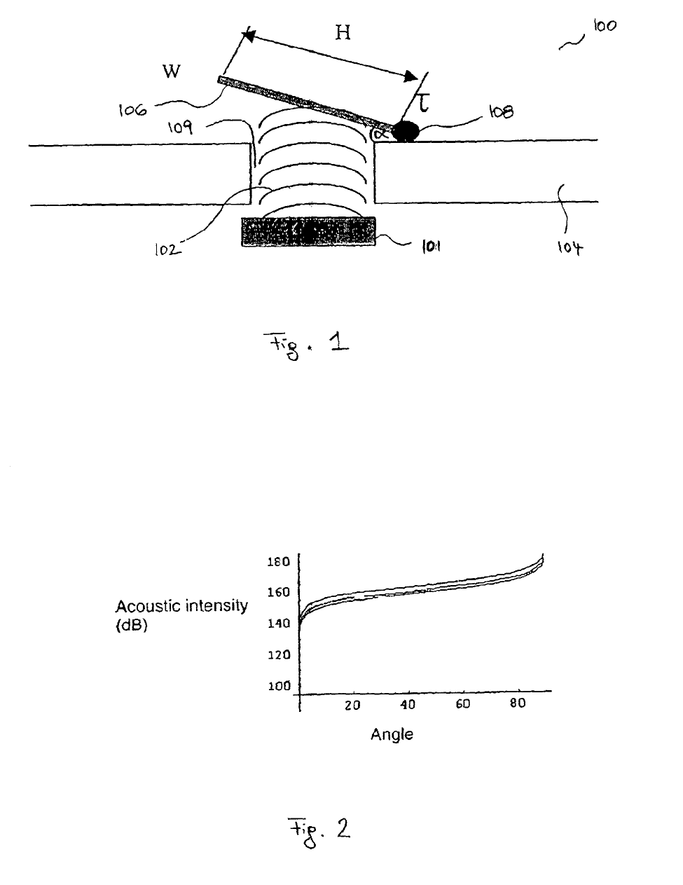

FIG. 1 shows a 2-dimensional (2-D) MEMS optical switch using acoustic actuation;

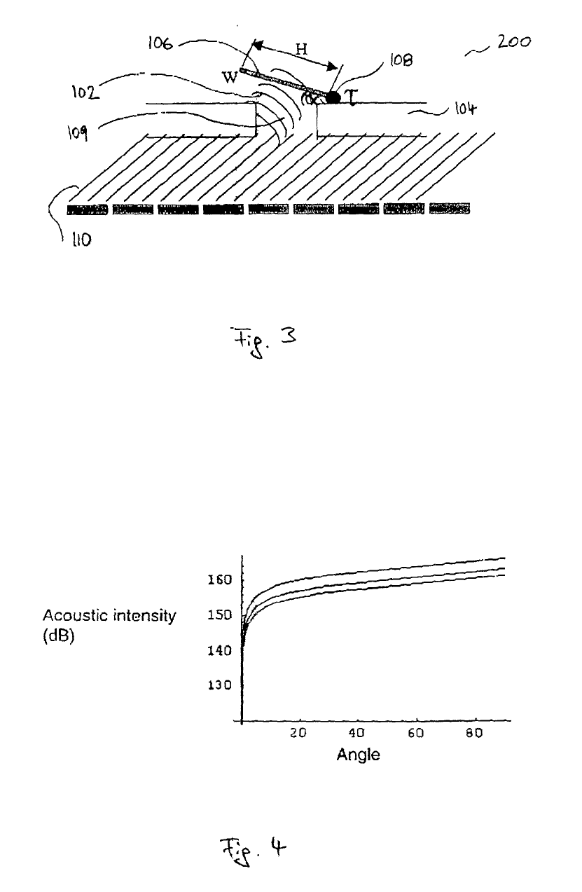

FIG 2 shows a plot of acoustic intensity vs. tilt angle for the optical switch presented in FIG. 1;

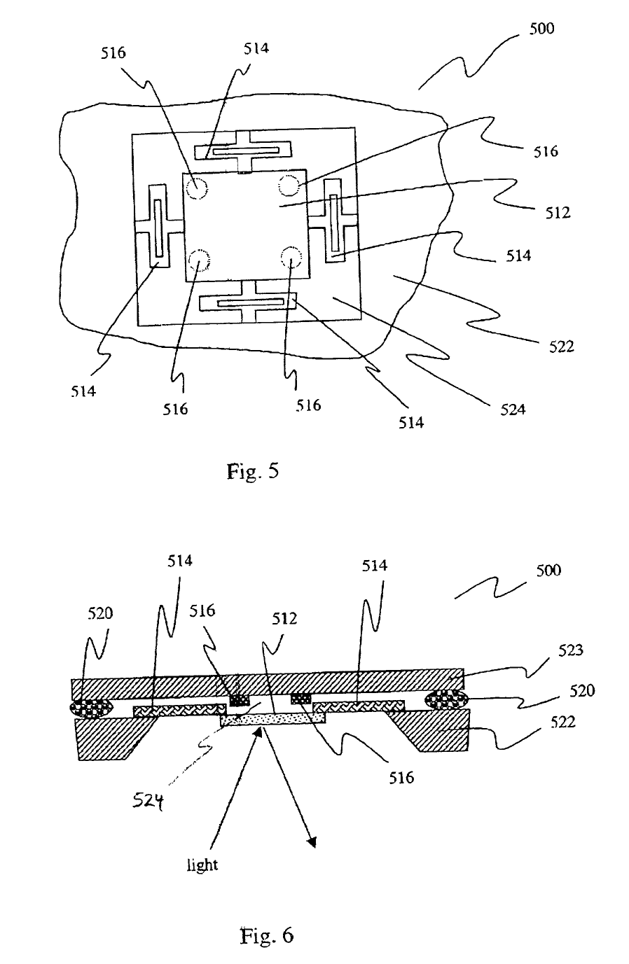

FIG. 3 shows another embodiment of an acoustically actuated 2-dimensional (2-D) MEMS optical switch wherein an acoustic wave is launched at an angle of 45 degrees;

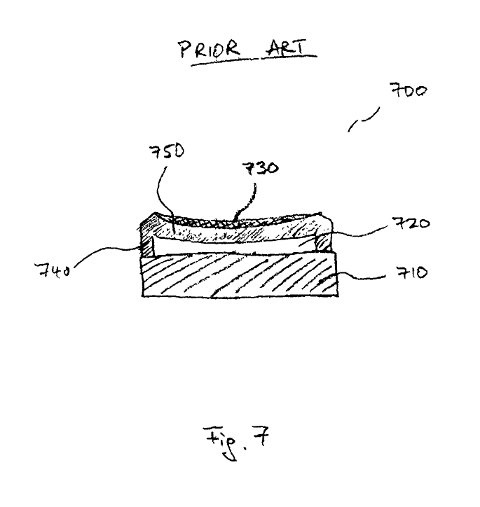

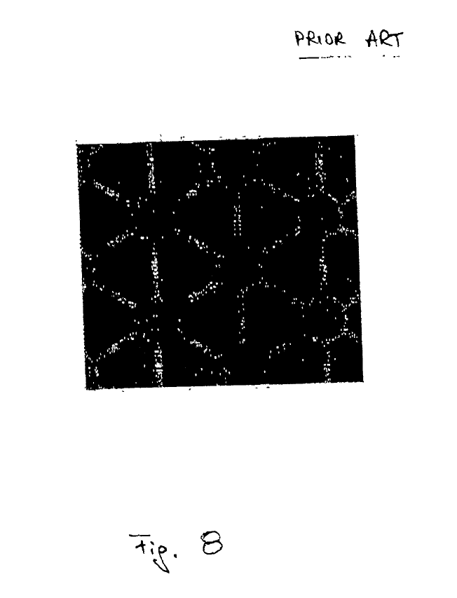

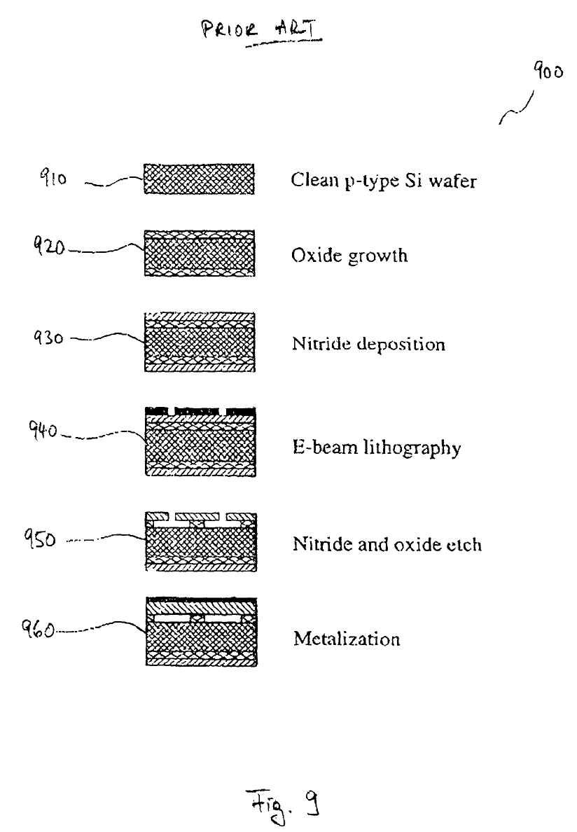

FIG. 4 shows a plot of acoustic intensity vs. tilt angle for the 2-D MEMS optical switch presented in FIG. 3;

FIGS. 5 and 6 show schematic views of an exemplary embodiment of a 3-D MEMS optical switch employing acoustic waves for movement of a mirror;

FIG. 7 shows a schematic view of one element of a prior art micromachined ultrasonic transducer (MUT);

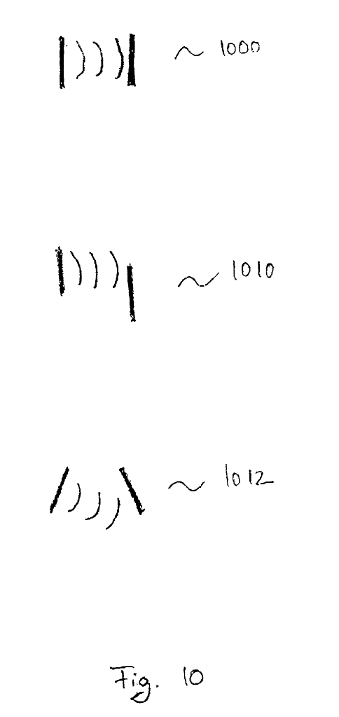

FIG. 8 presents MEMS structures on the surface of a silicon ultrasound device consisting of many such elements as shown in FIG. 7;

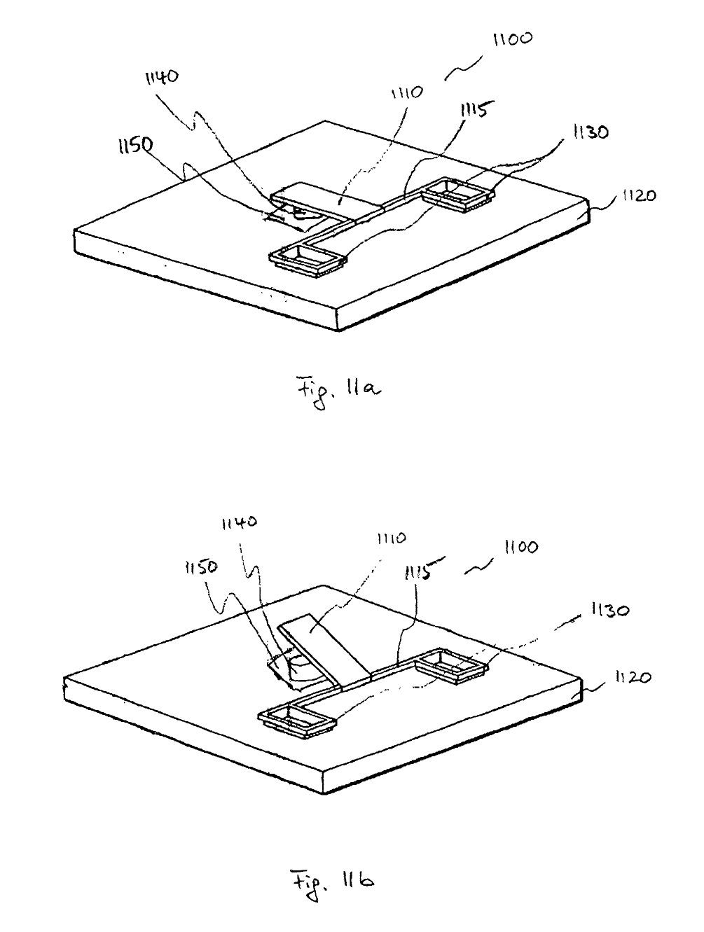

FIG. 9 shows a schematic diagram of the major steps of MUT fabrication;

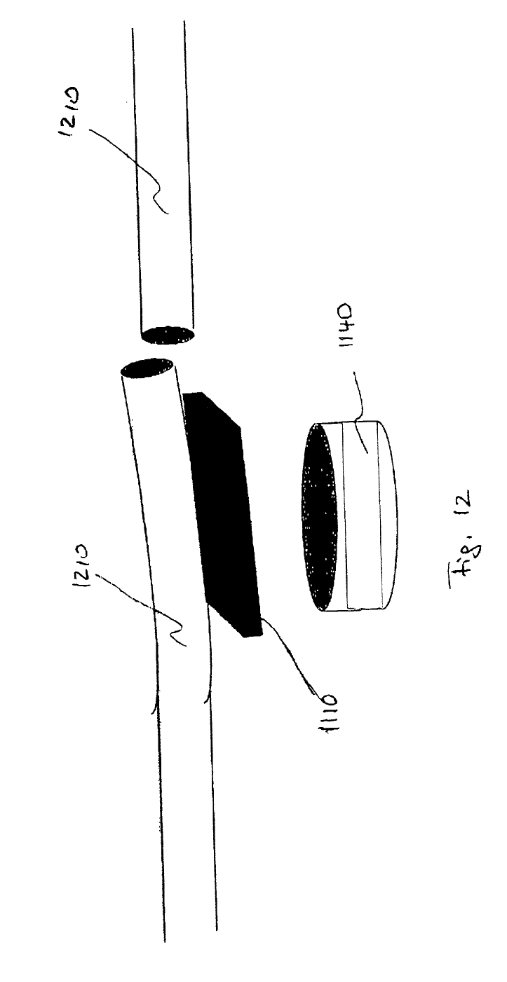

FIG. 10 shows a schematic view or properly and improperly aligned planar surfaces of the transmit and receive transducers;

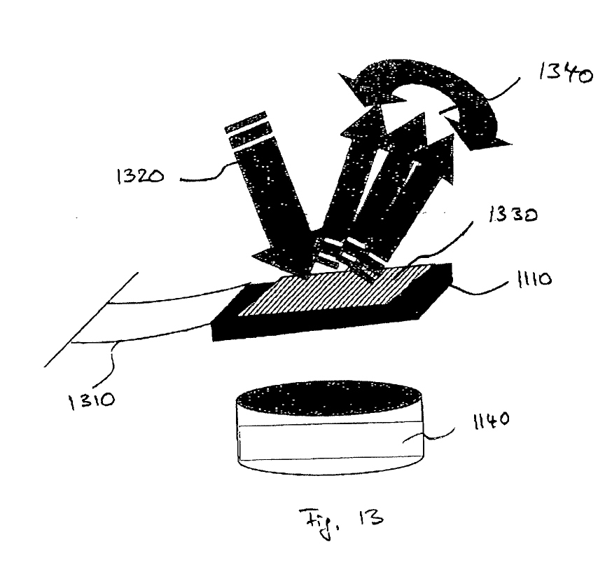

FIGS. 11a and 11b show another embodiment of a MEMS device having in acoustically actuated MEMS element in a rest position (FIG. 11a) and an elevated position (FIG. 11b);

FIG. 12 shows a schematic view of an acoustically actuated MEMS device being used as an optical attenuator;

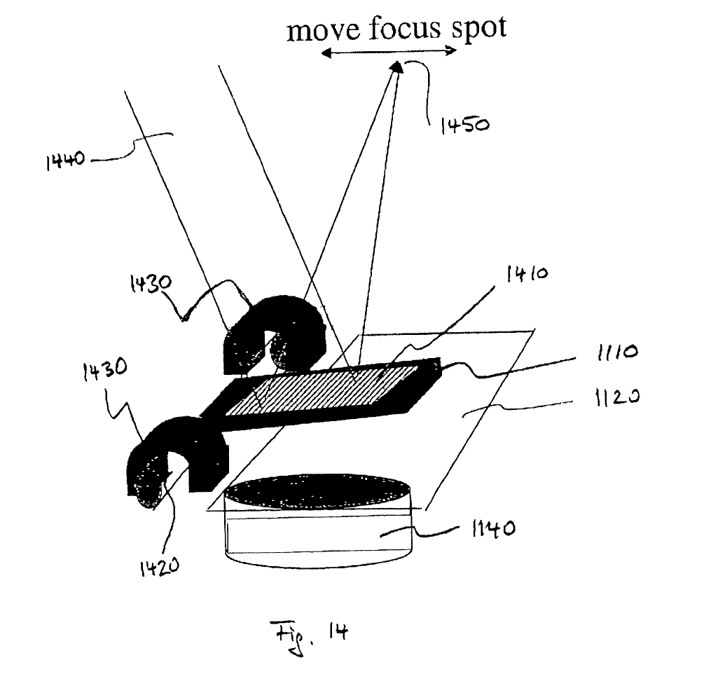

FIG. 13 shows a schematic view an acoustically actuated MEMS device being used us a spectral tuner;

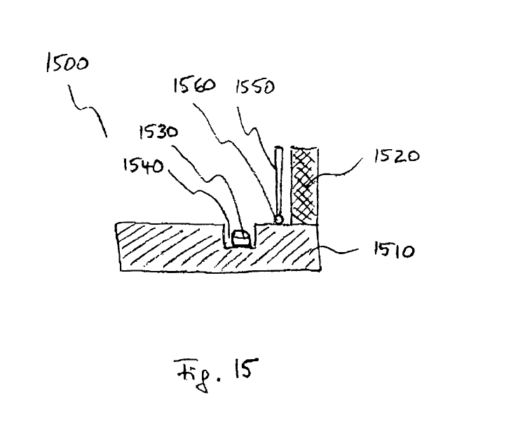

FIG. 14 shows a schematic view an acoustically actuated MEMS device being used to move a focus spot;

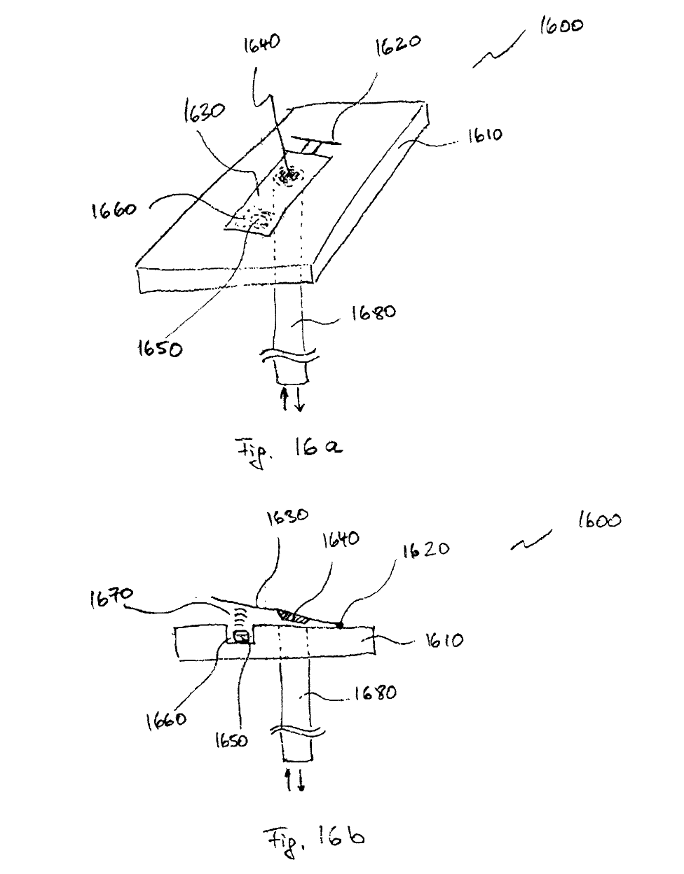

FIG. 15 shows a schematic view an acoustically actuated MEMS device having an electrostatic latch to hold a MEMS element in a vertical position;

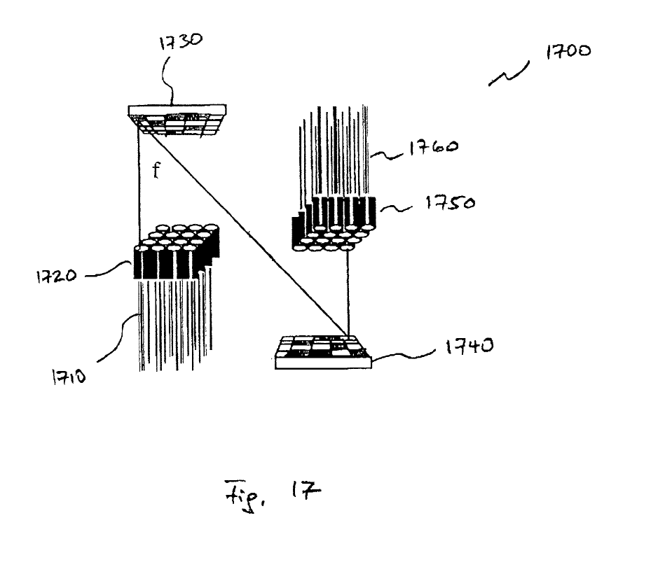

FIGS. 16a and 16b show another MEMS device in accordance with the present invention wherein an acoustically actuated MEMS element is used as a valve;

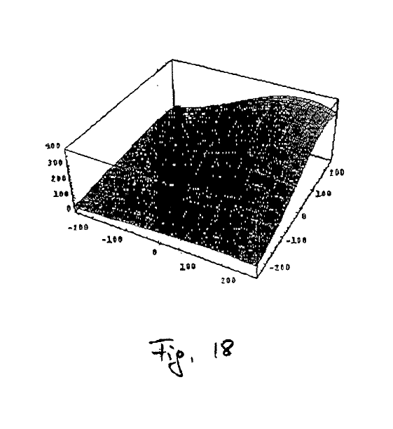

FIG. 17 shows an acoustically actuated optical switch having two arrays of micromirrors to perform a switching function; and

FIG. 18 shows a graph of acoustic radiation pressure generated under a mirror (Pa) versus position.

### DETAILED DESCRIPTION OF THE INVENTION

A sound wave carries energy from one place to another. If the sound wave is deflected from a deflecting surface, there is a momentum transfer between the sound wave and the deflecting surface. This momentum transfer is called radiation pressure and is used to move the deflecting surface. This radiation pressure is not the rise and fall of air pressure at the frequency of the sound but is a net momentum transfer that is a constant pressure. In a MEMS device acoustic forces can dominate over other forces such as gravity and friction.

The pressure exerted by a sound wave deflected from a non-absorbing surface is:

$${P}_{rad} = \frac{2 l}{c}$$

where P_{rad} is the radiation pressure (N/m²)

I is an acoustic intensity (W/m²)

c is a propagation velocity of sound (340 m/s in air)

The intensity of a sound wave is given by

$$I = \frac{1}{2} {ρ}_{0} c {ω}^{3} {\vert ξ \vert}^{2}$$

where ρ₀ is the density of air

ω is an angular frequency of the sound wave

ξ is an amplitude of the sound wave expressed as a particle displacement from a rest position. This can he related to the motion of the transducer that generates the acoustic wave.

Combining the two equations gives

P_{rad}=ρ₀ω³|ξ²

As is apparent from the above equations, the radiation pressure varies as the square of the frequency and the square of the amplitude of the sound. While it is advantageous to use as high an amplitude and frequency as the transducer can generate, the attenuation of sound in air also depends roughly on the square of frequency. The radiation pressure depends directly on the density of the gas. The density ρ₀ can be increased by pressurising the environment and/or by means of a composition of the gas which serves as an energy transfer medium of the radiation pressure. Sulfur hexafluoride (SF₆), for example, has approximately 5 times the density of air at the same pressure, and hence is better suited than air to transfer the radiation pressure of the acoustic wave.

Acoustic intensity is often expressed in dB relative to the threshold of hearing (10⁻¹² W/m²). On this scale, the loudest sound that does not lead to a vacuum in the rarefaction portion of the pressure wave is 191 dB.

FIG. 1 shows a 2-dimensional (2-D) MEMS optical switch 100 using acoustic actuation. A moveable element 106, such as a flap with a mirror, is shown to be fastened to a substrate 104 through fastening means 108, such as a ligature, a cantilever, a hinge, or any other fastening means that allow movement of the moveable element 106. An acoustic transducer 101 generates an acoustic wave 102. If the acoustic wave 102 is incident on the flap 106 via hole 109 the acoustic pressure raises the flap 106 by pushing the flap from a horizontal to a vertical position in which it is electrostatically clamped to an alignment surface as will be explained in more detail below. If desired, a control mechanism (not shown) is provided to allow any angular position of the flap between the horizontal and the vertical position. The raising of the flap 106 is a movement about one axis creating a two-dimensional movement.

If the fastening means 108 is sprung with a torque constant of τ [degrees]/(N-m) then the acoustic intensity I is related to an angle α of the moveable element 106 by

α≈τ(I/ν)*W*H^{′}/2

Typical micromirrors used to deflect optical beams have dimensions of W=700 microns and II=400 microns, with springs having torque constants of about 8 degrees per mN-μm.

The acoustic intensity required to raise the moveable element 106 of switch 100 to a predetermined angle is shown in FIG. 2. As is seen from this plot of acoustic intensity vs. tilt angle, the intensity required to raise the moveable element to the vertical position encounters another increase for tilt angles close to 90 degrees.

In accordance with one embodiment of the invention the frequency of the acoustic wave is higher than any resonance of the moveable element to avoid setting up vibrations in the moveable element. MEMS based acoustic actuators can be obtained for operating frequencies of up to several megahertz. At such frequencies the acoustic wavelength is of the order of 200 microns and consequently, the beam generated by even a small actuator is very narrow. A more detailed description of acoustic transducers is given below.

FIG 3 shows another embodiment or an acoustically actuated 2-dimensional (2-D) MEMS optical switch 200 wherein the acoustic wave 102 is launched at an angle of 45 degrees. In order to launch the acoustic wave towards the moveable element 106 at an angle other than zero degrees, two transducers of diameter on the scale of one acoustic wavelength are arranged under the same mirror as a phased array, with their drive phases relationships launching out of phase to steer the acoustic beam toward a side of a hole 109 through the substrate 104 to generate an aimed sound beam in the desired direction as a result of constructive sound wave interference. The reflection from this wall then drives the moveable element 106 starting from a bias angle of 4.5 degrees. Alternatively, an array of MEMS acoustic transducers 110 is used to launch the acoustic wave 102 through the hole 109 in the substrate 104 to lift the moveable element 106 by acoustic radiation pressure. In a typical acoustic transducer array, independent acoustic transducers are capable of being excited and interrogated at different phases. The angled launch is achieved by phasing the attenuator array located far enough below the moveable element 106 to establish far field conditions.

FIG 4 shows a plot of acoustic intensity vs. tilt angle for the 2-D MEMS optical switch 200. The plot shows the acoustic intensity required to move the moveable element through a prescribed angle with a launch at 45 degrees. As is seen from the plot, the maximum required acoustic intensity is reduced by about 20 dB in comparison to the plot of FIG. 2 or the zero degree launch. However, the advantage of this launch at 45 degrees has to be balanced against any loses incurred in the angled (45 degree) launch.

Acoustomechanical MEMS actuators can also be used to tilt micromirrors for use in optical switches using three-dimensional (3-D) beam steering. The advantage of acoustic actuation is assessed against capacitive actuation on the basis of force available per unit area and he advantage of using a pushing force rather than a pulling force.

FIGS. 5 and 6 show an exemplary embodiment of such a 3-D MEMS optical switch 500 employing acoustic waves for movement of a mirror 512. The mirror 512 is supported on a base 522 of the MEMS switch 500 and fastened thereto by flexible ligatures 514. These ligatures 514 allow the mirror 512 to tilt in two axes creating 3-dimensional movement. Acoustic actuators 516 are situated at four points in close proximity to the mirror 512. However, the minimum number of acoustic actuators 516 needed to steer the beam in two axes is three. In comparison to the 2-D switch described above, a minimum number of one acoustic actuator is needed to steer the beam in one axis. The acoustic actuators 516 omit an acoustic wave that creates pressure on the mirror 12 and causes it to be moved at the point of contact with the acoustic waive. A controller (not shown) controls an activation intensity of acoustic actuators 516 to control a degree of MEMS activation. The controller sends control signals to the acoustic actuator 516 to control the acoustic wave emitted and thus provide a controlled movement of the mirror 512. The mirror 512 is controlled, for example, by rotating it against a spring force and hence a balance between the acoustic force and the spring force sets the angle of mirror 512. In accordance with an embodiment of the invention, the controller has a mirror and a sensor to measure a position of a beam of light on the mirror which is representative of the position of mirror 512. The information about the position of mirror 512 is provided to a driver of the acoustic actuator via a feedback circuit, for example.

Base 522 is made or a silicon substrate such as commonly used in MEMS devices. The mirror 512 can be made of single crystal silicon on an Si -on -insulator wafer, for example, with a metallic coating for optical reflection. In such an exemplary configuration the mirror 512 overlies a hole 524 through base 522. The light is incident through the hole as shown in FIG. 6.

When a force is applied to the mirror 512, the force and the ligatures 514 control the movement of the mirror 512 and keep it fastened to the base 522. The ligatures 514 limit the movement of the mirror 512 according to the torsional and flexural capabilities to their material and structural characteristics. The ligatures 514 can be made of a flexible material, such as polysilicon. Advantageously, the mirror design presented in FIGS. 5 and 6 does not require a lifting mechanism to gain clearance above a substrate necessary for tilting as it is the case, for example, in electrostatically driven mirrors. There are no further limits on the tilt other than the torsional and flexural capabilities of the ligatures.

The acoustic actuator 516 is a transducer that emits an intense beam of sound at a high frequency towards the mirror 512. The frequency of the emitted acoustic wave should be higher than any resonance of the mirror 512 to avoid setting up vibrations in the mirror 512. For example, a frequency of 5 MHz provides a high enough frequency as this is approximately many times greater than the mechanical resonance of a structure like the mirror 512, thus the mirror 512 will not be affected by a cyclic pressure/fluctuation of the acoustic wave but will only experience a steady integrated momentum transfer from the acoustic wave.

The acoustic actuator 516 is fabricated on a separate wafer 523 and located above the mirror 512. The two wafers 522 and 523 are shown to be joined by bump bonds 520. If desired other similar processes of wafer joining may be used to combine the wafers. The bump bonds 520 further provide a separation between wafer 522 and wafer 523. A wafer—wafer distance of 100 to 200 microns is suitable. Alternatively, the acoustic actuator and the moveable element, such as a mirror, are all integrated on a same substrate using multi-layer techniques, such as LIGA and Foundry processes.

The acoustic actuator 516 is placed above the mirror 512 at a distance sufficient to separate the actuator 516 from the mirror 512 but close enough for the mirror 512 to receive a force great enough to move it by means of acoustic waves emitted from the actuator 516. The distance between the actuator 516 and the mirror 512 depends on the characteristics of the acoustic wave emitted by the actuator 516 and the size of the actuator 516. The actuator 516 may be shaped to focus the wave onto the mirror 512, such that the wave does not diminish quickly. For smaller acoustic actuators the distance is increased from that of a larger acoustic actuator. An increased wavelength also increases the distance at which the mirror 512 may be positioned from the acoustic actuator 516. For example, the distance between the acoustic actuator 516 and the mirror 512 may be between approximately 10 micron to 1 mm, or approximately 100 times the wavelength of the acoustic wave.

The acoustic actuator 516 emits a sound wave that reflects from the mirror 512. Momentum from the wave is transferred to the minor 512 resulting in a steady force being applied to the mirror 512. This application of pressure results in the movement of the mirror 512 against gravity and spring constants from the ligatures 514.

The acoustomechanical actuator is an efficient gas-coupled, such as air or sulfur hexafluoride, ultrasonic transducer that can launch an intense beam of sound at a high frequency toward the actuation point, i.e. the element to be moved. In accordance with an embodiment of the invention, the frequency used is of the order of 5 MHz. This frequency is several orders of magnitude beyond the mechanical resonance of a structure like a mirror and hence does not respond at the driving frequency.

Acoustic transducers launch sound waves that reflect from a planar surface of the moveable element. Momentum transfer from the acoustic wave to the moveable element results in a steady pressure that is exactly analogous to the optical radiation pressure. The acoustic radiation pressure is typically of the order of 110 to 1000 Pa. Such a pressure is capable of moving the moveable element against gravity and spring constants typical of MEMS devices.

The acoustic transducer used in accordance with an embodiment of the invention typically generates sound intensity levels of about 150 dB at a frequency of 5 MHz. Acoustic transducers can be safely operated at these conditions because acoustic waves at megahertz frequencies are strongly attenuated in millimeters of air. No audible sound is generated and the waves are of low power even though the intensity is high within fractions of a millimeter from the transducer.

Currently available acoustic transducer devices are between 50 and 200 microns in diameter and can be fabricated in arrays or patterns that can be made to match the corners of the moveable element, such as a mirror as shown in FIGS. 5 and 6.

U.S. Pat. No. 6,246,158 B1 to Ladabaum, incorporated herein by reference, discloses a microfabricated acoustic transducer or an array of such transducers formed on a single integrated circuit chip, and a method for making the same. Ladabaum et al. further describe the current state of the art of surface micromachined ultrasonic transducers (MUTs) in an article entitled “Surface Micromachined Capacitive Ultrasonic Transducers” published in IEEE Transactions on Ultrasonics, Ferroelectrics, and Frequency Control, Vol. 45, No. 3, May 1998, pages 678-690, which is incorporated herein by reference.

FIG. 7 shows a schematic of one element of a prior art MUT 700. A MUT consists of metalized silicon nitride membrane, such as an aluminum top electrode 730 on a silicon nitride membrane 750, which is separated from a silicon wafer substrate 710 (bottom electrode) by a thin (0.1-1 micron) vacuum-scaled gap, and being supported by a silicon nitride support 740. A vacuum cavity 720 is created between the metalized silicon nitride membrane 730, 750 and the bottom electrode 710. A transducer consists of many such elements as shown in FIG. 8 presenting MEMS structures on the surface of a silicon ultrasound device. It is possible to fabricate MUTs to form 1-D and 2-D transducer arrays by properly patterning thousands of membrane cells using a simple micromachining process. Fundamentally, these devices are capacitive structures. When a voltage is placed between the metalized membrane and the silicon wafer substrate, coulomb forces attract the membrane toward the substrate and stress within the membrane resists the attraction. If the membrane is driven by an alternating voltage, the tension in the membrane varies and causes it to vibrate, omitting ultrasonic waves. To generate high frequency acoustic waves the drumhead is put into tension with a bias voltage of about 100 V and the signal is introduced as a modulation at about 15-30 V peak-to-peak. The basic advantages of capacitive MUTs are their simple fabrication process and low cost.

MEMS technology affords silicon ultrasound transducers an important design advantage over piezoelectric transducers, a 50 dB better dynamic range in air. Because their thin, suspended membrane matches the acoustic impedance of air more closely than piezoelectric crystals, these transducers are more efficient than conventional piezoelectric transducers at transferring electrical energy into acoustic energy. For gas or air applications, MEMS acoustic transducers operate from 1 MHz to 5 MHz, frequencies that are ten-times higher than typical piezoelectric air/gas transducers. One advantage of MEMS technology is that it permits the fabrication of very small drums that emit high-frequency ultrasound.

There are three basic processes to manufacture MEMS devices. One process is surface micromachining which is most similar to Integrated Circuit (IC) processes. The materials are deposited on a surface of a wafer and sacrificial layers are used to release movable structures. Another process is bulk micromachining wherein large amounts of silicon substrate are removed to form diaphragms, beam, bridges and channels. The third process is LIGA (a German acronym for lithography, plating, and molding) to produce high aspect ratio part of metal, plastic and ceramics.

Micromachining is well suited for device fabrication because the dimensions of the membrane (microns) and residual stress (hundreds of Mpas) can be precisely controlled. Silicon and silicon nitride have excellent mechanical properties and can be readily patterned using a variety of techniques invented by the semiconductor industry.

FIG. 9 shows a schematic diagram 900 of the major steps of MUT fabrication. MUTs are fabricated by using techniques from the integrated circuits industry. A p-type (100) 4 inch silicon wafer is cleaned 910, and a 1 μm oxide layer is grown using a wet oxidation process 920. A 3500 Å layer of low-pressure chemical vapor deposition (LPVCD) nitride is then deposited 930. The residual stress of the nitride can be varied by changing the proportion of silane to ammonia during the deposition process. The residual stress used is approximately 80 Mpa. An electron beam lithography process then transfers a pattern of etchant holes to the wafer 940. The nitride is plasma etched, and the sacrificial oxide is etched away with hydrofluoric acid 950. These etchant holes define the geometry presented in FIG. 7. A second 2500 Å layer of LPVCD nitride is then deposited on the released membranes and thus vacuum sealing the etchant holes. The holes are patterned with an electron beam to seal the cavity. A metal layer is then evaporated onto the wafer 960. The wafer is then diced and the MUTs are mounted on a circuit board. A gold wire bond connects the top electrode to the circuit board. The lower electrode array also be bonded to the circuit board through a wire bond.

As the frequency of ultrasound increases, its signal attenuates more rapidly in air thereby decreasing the useful range of the device. Since the signal attenuation varies approximately with the square of the frequency, doubling the frequency results in quadruple attenuation and hence a four times reduction in range. Thus, for maximum signal strength, the devices should be placed as close together as possible. For example, at a frequency of 2 MHz, the MEMS acoustic transducers have a range of approximately 10 cm. Furthermore, it is important to carefully align these devices for optimal performance, as shown in conjunction with FIG. 10. The planar surfaces of the transmit and receive transducers must be aligned properly or a loss of signal strength will result. Properly aligned transmit and receive transducer surfaces are shown in 1000. Two examples of improperly aligned transmit and receive transducer surfaces are shown in 1010, resulting in a poor signal, and in 1012, resulting in no signal.

FIGS. 11a and 11b show another embodiment of a MEMS device 1100 having an acoustically actuated MEMS element 1110 in a rest position (FIG. 11a) and an elevated position (FIG. 11b). The acoustically actuated MEMS element 1130 having a planar surface is cantilevered about a beam 1115 and fastened to a substrate 1120 though anchors 1130 which are embedded within the substrate 1120. The acoustically actuated MEMS element 1110 is elevated from the rest position through the application of acoustic radiation pressure emitted from an acoustic wave generator 1140 located in a cavity 1150 of the substrate 1120 just below MEMS element 1110. In accordance with an embodiment of the present invention MEMS element 1110 is a mirror to switch an optical signal between different optical ports.

Alternatively, in accordance with a further embodiment of the present invention, the acoustically actuated MEMS device 1100 is used as an optical attenuator as shown in conjunction with FIG. 12. The acoustic wave generator 1140 emits an acoustic wave toward the planar surface of the acoustically actuated MEMS element 1110 which is used to support an optical waveguide 1210, such as a fiber. The upward movement of MEMS element 1110 causes a misalignment of the optical waveguide 1210 and hence an optical signal propagating through waveguide 1210 is attenuated as it cannot travel into the connecting end of waveguide 1210. A return force from the waveguide 1210 re-aligns both waveguide portions 1210 and the optical signal can travel into the connecting end of the waveguide.

FIG. 13 shows a schematic view of another embodiment wherein the MEMS device is employed as a spectral tuner. The acoustically actuated MEMS element 1110 is fastened to a substrate (not shown) via ligatures 1310. A diffraction grating 1330 is arranged on MEMS element 1110 such that an incoming beam of light 1320 is dispersed into different wavelengths 1340 which can be used to tune a spectral location.

FIG. 14 shows yet another embodiment of the present invention wherein the MEMS device is used to move a focus spot 1450. The acoustic wave generator 1140 is disposed on a substrate 1120 below MEMS element 1110. A holographic optical element or a Fresnel lens 1410 are disposed on MEMS element 1110 such that an incoming signal 1440 is focused to a spot 1450. By moving MEMS element 1110 and hence the holographic element or Fresnel lens 1410, the focus spot 1450 is moved from one position to another as indicated by FIG. 14. Such a device can be employed in a variety of applications, such as switching, wavelength division multiplexing, and the routing of signals. The MEMS element 1110 presented in FIG. 14 is fastened to the substrate 1120 by means of a rod 1420 supported in hinges 1430. The return force to return MEMS element 1110 into the horizontal position can be a spring force. Alternatively, a second acoustic wave generator is used to return MEMS element 1110.

FIG. 15 shows another example of a MEMS device 1500 in accordance with the present invention having an electrostatic latch 1520. An acoustically actuated MEMS element 1550 is fastened to a substrate 1510 through fastening means 1560. An acoustic transducer 1530 is provided in a cavity 1540 below MEMS element 1550. An acoustic wave omitted from transducer 1540 moves MEMS element 1550 from a horizontal to a vertical position. The provision of the additional latch electrode 1520 permits a maintenance of a small voltage to hold MEMS element 1550 in the vertical position.

FIGS. 16a and 16b show another MEMS device in accordance with the present invention wherein in acoustically actuated MEMS element has a valve. FIG. 16a presents a perspective view of MEMS device 1600 and FIG. 16 a side view. A MEMS element 1630 is fastened to a substrate 1610 through fastening means 1620. The MEMS element 1630 further has a valve 1640 arranged thereon such that when the MEMS element 1630 is in a horizontal position, the valve 1640 provides a seal to a passage 1680. When an acoustic transducer 1650 emits an acoustic wave 1670, the MEMS element 1630 is move into a horizontal position and the valve is removed from passage 1680 permitting a passage of fluids therethrough. The acoustic transducer 1650 is disposed in a hole 1660 within substrate 1610. The double arrow at the bottom of passage 1680 indicates a bi-directional flow of fluids through the passage. Alternatively, a second passage with its own MEMS element and valve are provided such that one passage is used to provide a fluid to the MEMS device 1600 and the second passage is used to remove the fluid from device 1600.

FIG. 17 shows an optical switch 1700 having two arrays of micromirrors to perform a switching function. A beam of light is launched into switch 1700 via an input fiber bundle. Each fiber of the input fiber bundle has a microlens 1720 for imaging the beam of light to a micromirror on the first array of micromirror 1730. Through a movement of the micromirror on the first array 1730, the beam is switched to a micromirror on a second array of micromirrors 1740. By moving this mirror on the second array 1740, the beam of light is steered to any fiber of the output tiber bundle 1760 having microlenses 1750. In accordance with an embodiment of the present invention, the movement of the micromirrors on the first and second array is performed through acoustic actuation.

The linear equations of acoustics show that the pressure to first order is a simple sinusoidal oscillation, and the average over time does not result in a change in average pressure. Nonzero average forces arise due to second-order effects. Thus the acoustic radiation pressure is small relative to the sinusoidal pressure fluctuations and requires high acoustic levels to provide a significant response.

The theory of acoustic radiation pressure (ARP) has developed from the foundation given by Lord Rayleigh in 1878 to almost the present day. There are two basic formulations: one involving interaction with the acoustic medium due to Langovin, the other due to Rayleigh in which there is no interaction with the undisturbed medium.

The radiation pressure relates to the time-averaged momentum flux per unit area imparted to the surface under consideration. Surfaces which are acoustically hard are considered, so that the surface does not deform in any way at the ultrasonic frequency. Thus reflections are perfect, and standing waves are built up. In a driven cavity the acoustic fields can build up to very high levels. This will help in increasing the ARP. The radiation pressure becomes:

Pᵣ=(γ+1)ρₒυₒ²/8

where γ is the parameter in the adiabatic equation for the gas, ρₒ is its density, and vₒ is the amplitude of the particle velocity in the standing wave. For a diatomic gas such as nitrogen or oxygen in air, γ=7/5.

Considering the initiating wave as having a particle velocity vₒ/2, then a single reflection at normal incidence from a hard surface results in a standing wave with a net velocity of vₒ. The intensity I of the source is:

I=½ρₒc (vₒ/2)²,

where c is the velocity Or sound. This results in a radiation pressure:

Pᵣ=(γ+1)I/c,

The increase in radiation pressure can be traced to the increased stiffness of the adiabatic nature of sound.

Now γ can be quite accuracy related to the number of rotational modes of a gas molecule by:

γ=(5+N)/(3+N)

where N is the number of rotational degrees of freedom. It is 5/3 for a perfect monotonic gas like helium (N=0), 7/5 for a diatomic molecule such as hydrogen or air (N=2). and 4/3 for non co-linear molecules (N=3). Thus γ does not change much for different gases.

To frame the relationship between ARP and the sound pressure in a plane wave, the relation ρ=ρₒcv can be used to show that the radiation pressure Pᵣ relates to the sound pressure p as:

Pᵣ/p=½p/(ρₒc²).

For a sound lavel of 100 dB, the acoustic pressure is about 2 Pascal, and Pᵣ is smaller than p by a factor of about 140,000. But Pᵣ is proportional to p², so it grows rapidly with sound level.

In order to maximize the ARP, the acoustic intensity needs to be maximized. The acoustic intensity can be written as:

I=½ρₒc(ωξ)²,

where ω is the initial frequency, and ξ is the amplitude of the wave which in turn is the amplitude of oscillation of the planar transducer used to make a plane acoustic wave. At a frequency of 4 Mhz and a displacement amplitude of 500 nm, the peak pressure in the sound wave is just over 5000 Pascal (1/20^{th} atmosphere), and represents about 165 dB sound pressure level for normal air. The radiation pressuring from an acoustically hard reflection would be about 88 Pascal.

Assuming an ARP of 88 Pascal on a flap of 700×400 μm, the force will be 2,464×10⁻⁵ N, while neglecting attenuation. Attenuation is relatively small at frequencies of a few MHz for the distances encountered here. With a mass of 6 μg=6×10⁻⁹ kg, the acceleration of the flap is about 4100 m/s². Gravity is indeed negligible. With no restraint, the flap would move 500 μm in about 500 μs.

If the radiation force must hold open an angular spring with torque of about 10⁻⁹ N-m, the force on a 200 μm arm must be about 5×10⁻⁵ N. roughly twice the force on the flap in the paragraph above.

An electrostatic latch was described above to hold a flap in a vertical position. In accordance with another embodiment the flap is hinged so as to vibrate at some natural frequency. Using an angular spring of 10⁻⁹ N-m/radian, and a mass of 6 μg with length 400 μm hinged at one end, the natural frequency turns out to be about 280 Hz. If the ultrastrinic transducer is pulsed at this frequency and build up the resonance over time, at which point a clamp can be invoked. The necessary acoustic energy may be reduced, but the switching time may need to be longer.

There is no omnidirectional component to the ARP. The momentum flux is a vector and a plane wave directed tangentially along a boundary has no ARP.

The ARP can be increased in several ways.

(1) The ARP is directly proportional to the density of the gas. Hence the pressure of the gas and its molecular weight should be high. SF₆ has a molecular weight of 146 compared to 28 for nitrogen and hence a higher ARP is gained.

(2) The frequency of the ultrasound should be made as high as practical, since the particle velocity is the product of ωξ.

(3) The transducer can be shaped to focus the radiation onto the target. This can he advantageous in other ways too, since the resulting spherical waves would have in ARP which may not diminish as quickly as a flap is opened by 90°.

At very high frequencies, solid is highly damped. The viscosity and heat conduction of the gas are involved, and the attenuation of the pressure can be written its e^{ax}, where the value of a is:

a=½(w/c)²[I_{υ}^{′}+(γ−1)[ₕ],

where

I_{υ}^{′}=(4/3+η/μ)/ᵥ=(4/3+η/μ)// γ^{½},

and

└ₕ=1.6 ┐/γ^{½}.

In these equations the various lengths relate to viscosity and heat conductivity parameters, and depend ultimately on the molecular mean free path /. The attenuation, while very small at audio frequencies, becomes important at megahertz frequencies. But the mean free path is inversely proportional to as pressure. Hence the attenuation becomes less as the pressure is raised, and the radiation pressure increases to boot.

At intermediate frequencies, typically well below 1 Mhz, polyatomic gases can exhibit attenuation very much larger (i.e. CO₂) than the classical effects of viscosity and heat conductivity. It is assumed that the frequencies used in MEMS will be high enough to avoid these regions. Any particular gas should be checked for acoustic properties at megahertz frequencies before use.

A gas tends to lose its ability to transmit sound when the wavelength gets smaller, since heat flows more readily and the adiabatic nature of the sound is compromised. When the wavelength of the sound is of the order of the mean free path, sound is essentially impossible to define. The loss and propagation are about equal so that the sound disappears in about a wavelength. A higher gas pressure decreases the mean free path so that the frequency at which these effects occur is greatly increased.

In order for the phased array arrangement of acoustic transducers to give a powerful beam at 45°, the strips making it up must be relatively small compared to λ.

A control of the activation intensity of the acoustic transducer can be used to control the degree of MEMS activation. When actuated, the MEMS element is rotated against the spring force, for example. A balance between the acoustic force and the spring force sets the angle of the moveable MEMS element.

Modeling—3-D MEMS Switch

The pressure that can be generated by a transducer array under a mirror as shown in FIG. 5 and 6 was calculated using the above described theory. The mirror is 500 microns square. Four transducers were located under each quadrant of the mirror on 110 micron spacings, separated from the mirror in the vertical direction by 210 microns. The transducers were 100 micron in diameter, and were arbitrarily assumed to radiate in a Lambertian pattern. An SF₆ environment at one atmosphere pressure is assumed. The acoustic frequency is 1 MHz. The pressure distribution is shown in FIG. 18 for the situation where all four acoustic transducers in one quadrant are activated.

The two components of torque are obtained from

$$\{ Tx , Ty \} = \{ {\int }_{250}^{250} {\int }_{- 250}^{250} xP ( x , y ) ⅆ x ⅆ y , {\int }_{- 250}^{250} {\int }_{- 250}^{250} yP ( x , y ) ⅆ x ⅆ y \}$$

For the case shown in FIG. 3 one obtains {Tx,Ty}={3,3} mN-μm, or a torque of about 4.25 mN-μm in the diagonal direction. By activating the transducers under the other quadrants with appropriate phrases, the torque could be increased.

An estimate of the torque required to move a mirror tethered by a layout of four serpentine springs was carried out. About 7 mN-μm would be necessary for a 20 degree deflection with the configuration selected. Thus, a movement of more than 10 degrees is possible with a simple tethered mirror using MEMS acoustic actuation.

The effect of the oscillating sound pressure of the tilting plate can be estimated. The moment of inertia of a square plate around its centre, parallel to a side, is

$$l = ρ T {\int }_{- D12}^{D12} {\int }_{- D12}^{D12} {y}^{2} ⅆ x ⅆ y$$

where ρ is the density of the plate=2000 kg/m³. T is its thickness=10⁻⁵ m, and D is the length of one side of the square=500*10⁻⁶ m. The value is I=10⁻¹⁷ kg m².

The angular displacement of the plate as a function of a sinusoidal torque with amplitude A is given by the double integral of the torque divided by the moment.

$$0 ( l ) - \int \int \frac{A sin ( ω t ) ⅆ t ⅆ t}{l} = \frac{A sin ( ω t )}{{ω}^{2} l}$$

A torque of about 5 mN-μm can be generated by the acoustic radiation. The maximum radiation pressure under these conditions is about 100 Pa, or about 1/10 atm. The maximum possible amplitude for the sound is 1 atm, which would produce a vacuum in the rarefactions. Assuming that the oscillating torque exerted by the sound has an amplitude A=500 mN-μm (100 times the torque exerted by the radiation pressure). The angular oscillation is therefore

$$θ ( t ) = Θ sin ( ω t ) = \frac{500 \cdot {10}^{- 3} \cdot {10}^{- 6}}{4 {π}^{2} {10}^{14} \cdot {10}^{- 17}}$$

If the frequency is 10 MHz, the amplitude of this oscillation is 0.000013 radians=0.0007 degree. Hence no problem of mirror oscillation at a drive frequencies in the range 3-10 MHz is expected.

The above described embodiments of the invention are intended to be examples of the present invention and numerous modifications, variations, and adaptations may be made to the particular embodiments of the invention without departing from the spirit and scope of the invention, which is defined in the claims.

What is claimed is:

1. A MEMS acoustic actuator comprising:
a substrate;
an acoustic wave generator for generating an acoustic wave, said acoustic wave generator being disposed on the substrate; and
a moveable element for receiving the acoustic wave, said moveable element being operatively connected to the acoustic wave generator such that the acoustic wave generator is capable of exerting sufficient acoustic radiation pressure for moving staid moveable element.

2. The MEMS acoustic actuator as defined in claim 1 wherein the moveable element comprises a planar surface for receiving and deflecting the acoustic wave.

3. The MEMS acoustic actuator as defined in claim 2 wherein the substrate comprises a cavity for accommodating the acoustic wave generator and for directing the acoustic wave of the planar surface.

4. The MEMS acoustic actuator as defined in claim 2 further comprising another substrate for supporting the moveable element.

5. The MEMS acoustic actuator as defined in claim 4 further including substrate joining bonds for joining the substrate and the other substrate and for providing a sufficient separation between the acoustic wave generator and the moveable element.

6. The MEMS acoustic actuator as defined in claim 3 further comprising fastening means for moveable attaching the moveable element to the substrate.

7. The MEMS acoustic actuator as defined in claim 6 wherein the fastening means is one of a ligature, a cantilever, and a hinge.

8. The MEMS acoustic actuator as defined in claim 4 further comprising fastening means for moveably attaching the moveable element to the other substrate.

9. The MEMS acoustic actuator as defined in claim 8 wherein the fastening means is one of a ligature, a cantilever, and a hinge.

10. The MEMS acoustic actuator as defined in claim 2 further comprising control means for controlling a movement of the moveable element.

11. The MEMS acoustic actuator as defined in claim 10 wherein the control means is an electrostatic latch for holding the moveable element in a vertical position.

12. The MEMS acoustic actuator as defined in claim 10 wherein the control means comprise a sensor for detecting a position of a beam of light and a feedback circuit for providing the detected position to the control means, said control means for adjusting the position of the moveable element in dependence upon the detected position.

13. The MEMS acoustic actuator as defined in claim 2 comprising at least 3 acoustic wave generator, for providing movement of the moveable element in two axes.

14. The MEMS acoustic actuator as defined in claim 2 wherein the moveable element is one of a mirror, a waveguide, a diffraction grating, a holographic optical element, a Fresnel lens, and a valve.

15. The MEMS acoustic actuator as defined in claim 2 wherein the radiation pressure is between 100 to 1000 Pa.

16. The MEMS acoustic actuator as defined in claim 2 wherein the acoustic wave generator is capable of generating a sound intensity level of 150 dB a frequency of approximately 5 MHz.

17. A method of actuating a MEMS device comprising the steps of:
launching an acoustic wave; and
receiving the acoustic wave with a moveable element such that the acoustic wave exerts sufficient radiation pressure for moving said moveable element.
